(19) United States
(12) Patent Application Publication
(10) Pub. No.: US 2010/0211854 A1
(43) Pub. Date: Aug. 19, 2010

(54) METHODS AND SYSTEMS FOR PROVIDING DIFFERENT DATA LOSS PROTECTION

(76) Inventors: Zhenyu Wu, Plainsboro, NJ (US); Jill Mac Donald Boyce, Manalapan, NJ (US); Alan Jay Stein, Princeton Junction, NJ (US)

Correspondence Address: Robert D. Shedd, Patent Operations;THOMSON Licensing LLC, P.O. Box 5312, Princeton, NJ, 08543-5312, US

(21) Appl. No.: 12/733,345

(22) PCT Filed: Aug. 27, 2008
(86) PCT No.: PCT/US2008/010150

§ 371 Date: Feb. 24, 2010

Related U.S. Application Data
(60) Provisional application No. 60/966,791, filed on Aug. 30, 2007.

(51) Int. Cl. H03M 13/05; G06F 11/10

(52) U.S. Cl. 714/776; 714/E11.032

(57) ABSTRACT

This invention relates to methods and apparatus for partitioning a data word into a protected region and an unprotected region in the link layer, forward error correction of a DVB-H module to provide unequal error protection of frames during forward error correction of the frames. IP-datagrams are encapsulated for coding after a pre-loading stage is initiated so that the reliability and importance of data in data frames corresponding to the IP-datagrams can be determined. Unequal error protection is further achieved by padding zeros in the unprotected region.

### CROSS-REFERENCE TO RELATED APPLICATIONS

This application claims priority from U.S. Provisional Application Ser. No. 60/966,791, filed on Aug. 30, 2007.

### FIELD OF THE INVENTION

This invention relates generally to data transmission systems. More particularly, this invention relates to data transmission systems which utilize data frame formats which are encoded in a DVB-H format and which receive unequal error protection (UEP) through forward error correction (FEC) techniques

### BACKGROUND OF THE INVENTION

User data delivered through a DVB-H system is subject to losses due to channel impairment introduced during transmission. The link layer, forward error correction (MPE-FEC) is a module in DVB-H to provide error protection against data losses. User data often exhibit differences in importance or error sensitivity, which implies that benefit may be possible from applying different strengths of error protection. However, the MPE-FEC can only provide equal error protection for each time slice as specified in the standard. As a result, when the FEC decoding in MPE-FEC fails, user data is lost indiscriminately. This can cause significant degradation of quality of service (QoS) for DVB-H services such as video and audio streaming.

Referring to FIG. 1, a known DVB-H system is illustrated. As is understood by those skilled in the art, the system comprises a transmitter end 10 which receives IP datagrams and a receiver end 20 which outputs IP-datagrams. The system of FIG. 1 generally processes MPE-FEC frames, the structure of which is illustrated schematically in FIG. 2. FIG. 3 generally illustrates an MPE and MPE-FEC frame format. As specified in the DVB-H standard and as described below with respect to FIGS. 1, 2, and 3, for the IP-datagrams from each time slice, the following operations are taken by the MPE-FEC if it is used.

At the transmitter end 10, the IP encapsulator 30 loads the IP-datagrams of a time slice into the MPE-FEC frame 32 inside the MPE-FEC module 34 for Reed-Solomon (RS) encoding 36. During the construction of the ADT (Application Data Table), the IP-datagrams are introduced vertically column-wise into the table from left to right as is shown in FIG. 2. If an IP-datagram does not end exactly at the bottom of a column, the next IP-datagram finishes that column and begins filling the next column in ADT from top to bottom. If the IP-datagrams of a time slice do not exactly fill ADT, the remaining bytes in the table are padded with zeros. Once ADT is filled, an RS (255, 191) code is applied row-wise across the columns of ADT. For each row of ADT, 64 RS parity symbols are generated to fill the corresponding row in RSDT (Reed-Solomon Data Table). The corresponding RS code rate is 0.75 without padding or puncturing.

After the construction of both ADT and RSDT, the data in the MPE-FEC frame is packetized and forwarded to MUX 40 and the DVB-T modulator 50. In particular, each IP-datagram from ADT is encapsulated into an MPE section, and the data from each column of RSDT is encapsulated into an MPE-FEC section. Both section headers contain a 4-byte real time parameter field designated as “MAC 1”-“MAC 4”. The field includes a 12-bit start address, which records the start position in byte number of the corresponding IP-datagram or RS data column with respect to the top-left corner of the table. The field also includes 1-bit flags to signal end-of-table and end-of-frame, as well as the 18-bit delta_t parameter to indicate the start time of the following burst of the same ES. In the MPE-FEC section header, there is a 1-byte field designated as “padding column”, and it is used to signal the number of complete padding columns in ADT. The output of the modulator 50 is output to the channel 60 as is conventionally known.

At the receiver end 20, the channel is demodulated by the demodulator 70 and the IP decapsulator 80 then discards any section of the time slice that is not correctly received by checking the CRC 32 field at the end of each section. It then loads the remaining sections into the MPE-FEC frame for MPE-FEC decoding. The MPE-FEC frame is initially marked as “unreliable” for each of its byte positions. With the start address recorded in the section header, the IP decapsulator 80 is able to introduce each section to the correct position in the frame, and mark the occupied position by the section as “reliable”. When an MPE-FEC section is loaded, the IP-decapsulator retrieves the padding information from the “padding column” field in its section header, and marks the corresponding columns in ADT as “reliable”. If the last MPE section in ADT is correctly received as indicated by the end-of-table flag in its header, the unoccupied byte positions from the last column from the section are marked as “reliable”. After this procedure is completed, except for the last MPE section case above, all the byte positions marked as “unreliable” in the frame correspond to lost sections.

If there is any MPE section loss, the IP decapsulator 80 performs erasure-based RS (255, 191) decoding 82 row-wise across all the columns of the frame. With the marked frame, the RS decoder knows in each codeword (a row in the frame) which positions are correct and which positions are erasures, and is able to recover up to 64 missing bytes per row in its decoding. If the number of missing bytes is more than the RS decoder can recover, it stops decoding and leaves the row unchanged. After the RS decoding is applied for each row, the IP decapsulator only outputs the correct IP datagrams in ADT by checking the CRC 32 field in an MPE section.

The FEC protection strength 84 provided by MPE-FEC can be controlled by adjusting the RS code rate to ultimately produce MEP frames 86. This in turn can be realized by adjusting the number of padding columns in ADT and the number of punctured RS columns in RSDT. Suppose x columns in ADT are designated as padding columns. This changes the original RS code from (255, 191) to (255, 191−x), which effectively lowers the code rate and increases the code strength. On the other hand, suppose y columns in RSDT are punctured. This changes the RS code to (255−y, 191), which increases the code rate and weakens the code. Changes can only be applied on a frame-by-frame basis because of the packetization and signaling restrictions.

As evident from the above, by the default operation in the standard, all IP-datagrams from a time slice are coded with the same RS code and thus receive the same amount of FEC protection. In order to provide different levels of FEC protection via MPE-FEC, adjusting the numbers of padding columns and/or puncturing columns is the only plausible way. However, such adjustment can only happen on an MPE-FEC frame (or a time slice) basis in the standard. As the size of an MPE-FEC frame can range from 256×191 to 1024×191 bytes, the granularity of such a method is relatively coarse. It either requires that IP-datagrams of similar importance come in the unit of an MPE-FEC frame (or a time slice) by nature, or some IP-datagram level reordering needs to be performed. However, such requirements are hard to meet for low bit rate, delay sensitive multimedia services such as video and audio streaming.

An alternative method to provide UEP through MPE-FEC takes the original MPE-FEC frame for a time slice and breaks it into several so called “peer MPE-FEC matrices”. Each such sub-frame can then be coded with a RS codeword with different code rate in the form of (255−x−y, 191−x). The total length of all the RS codewords maintains as 255 to maintain the same total bit rate. These sub-frames are sent back to back, such that the overall length of the bursts is equal to the original time slice. This is realized by setting the parameter delta_t to 0 in these MPE section headers. A disadvantage with this method is that each sub-frame is coded with a separate RS code with shorter codeword length, which is a subset of original 255 bytes. Shorter codeword length reduces the FEC correction capability. So for this method, even for those sub-frames coded with lower RS code rates, the drop in the FEC performance due to shorter codeword lengths may offset the protection gains. Therefore, the UEP is obtained at the cost of degradation of FEC protection strength.

Unequal error protection (UEP) functionality via forward error correction (FEC) within a time slice is not available in the current MPE-FEC module of the DVB-H standard. It would be desirable to provide UEP functionality within the MPE-FEC module without any change to the existing protocols and produces standard compliant output bit streams. Such results have not heretofore been achieved in the art.

### BRIEF SUMMARY OF THE INVENTION

The aforementioned long-felt needs are met, and problems are solved, by methods and apparatus provided in accordance with the present invention. In preferred embodiments, the methods and apparatus comprise partitioning a data word into a protected region and an unprotected region through the link layer, forward error correction of a DVB-H system to provide unequal error protection of frames during forward error correction of the frames.

### BRIEF DESCRIPTION OF THE DRAWINGS

FIG. 1 is a schematic diagram of known DVB-H systems.

FIG. 2 is an example of a known MPE-FEC frame generally useful in DVB-OH systems.

FIG. 3 is an example of an MPE-FEC section format related to the frame of FIG. 2.

FIG. 4 is an example of a modified MPE-FEC frame provided in accordance with the present invention.

FIG. 5 is a diagram of a preferred embodiment of the invention.

FIG. 6 is a flow diagram of a preferred method for realizing the IP-encapsulator of the invention.

FIG. 7 is another flow diagram of a preferred method for realizing the IP-decapsulator of the invention.

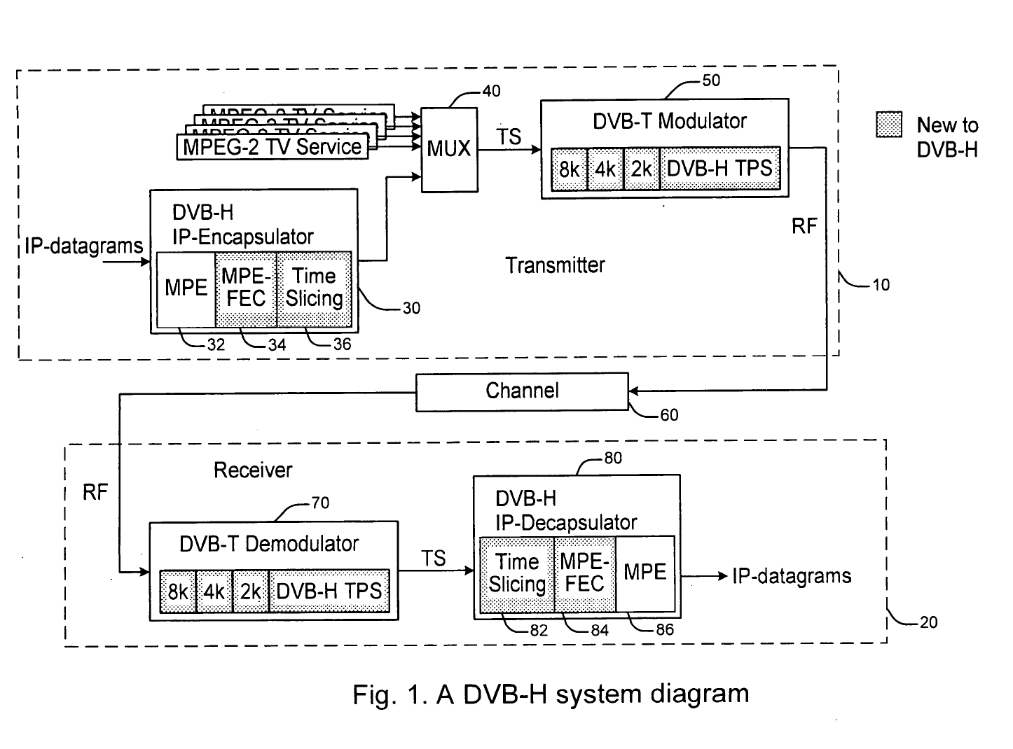

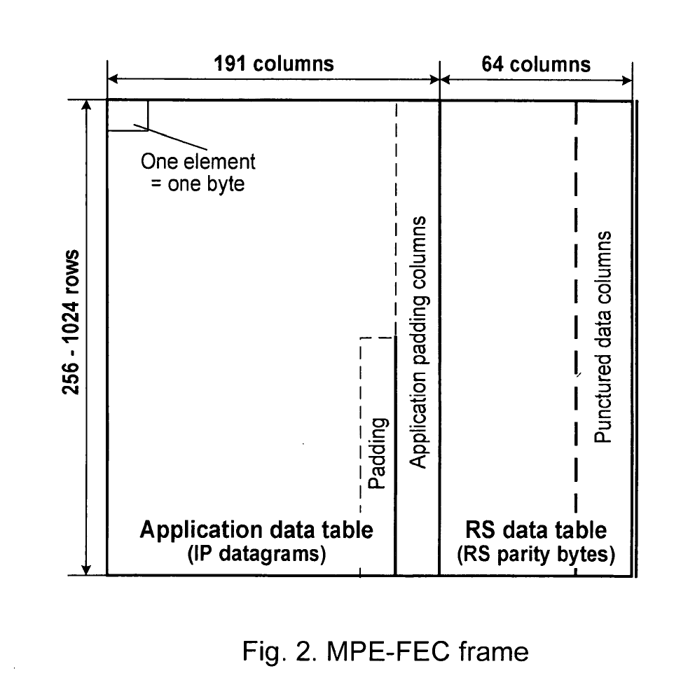

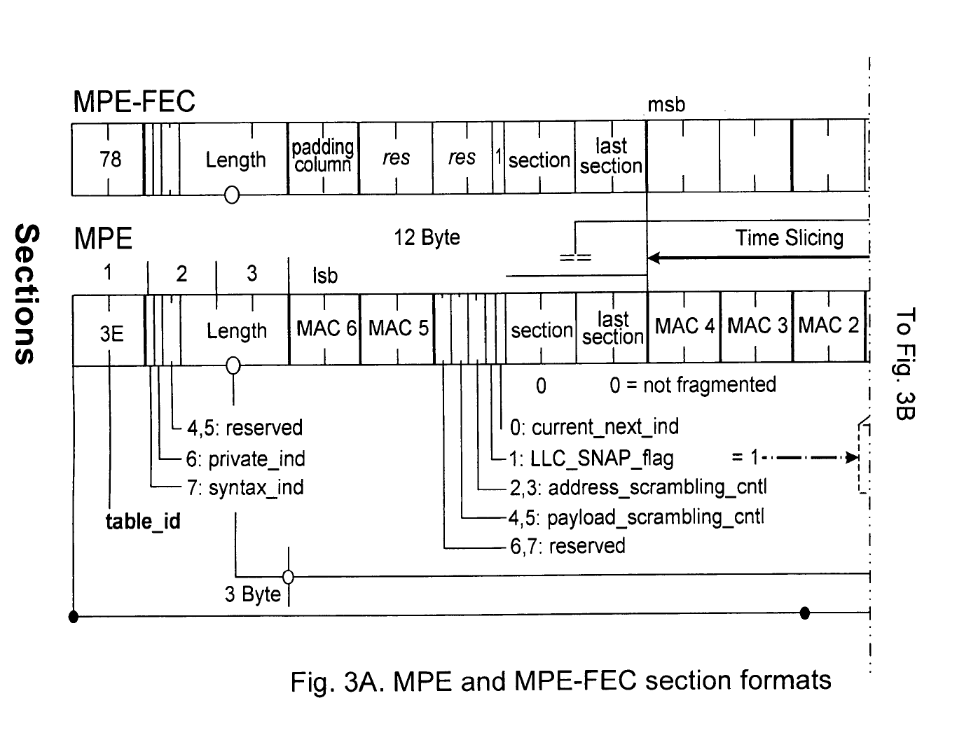

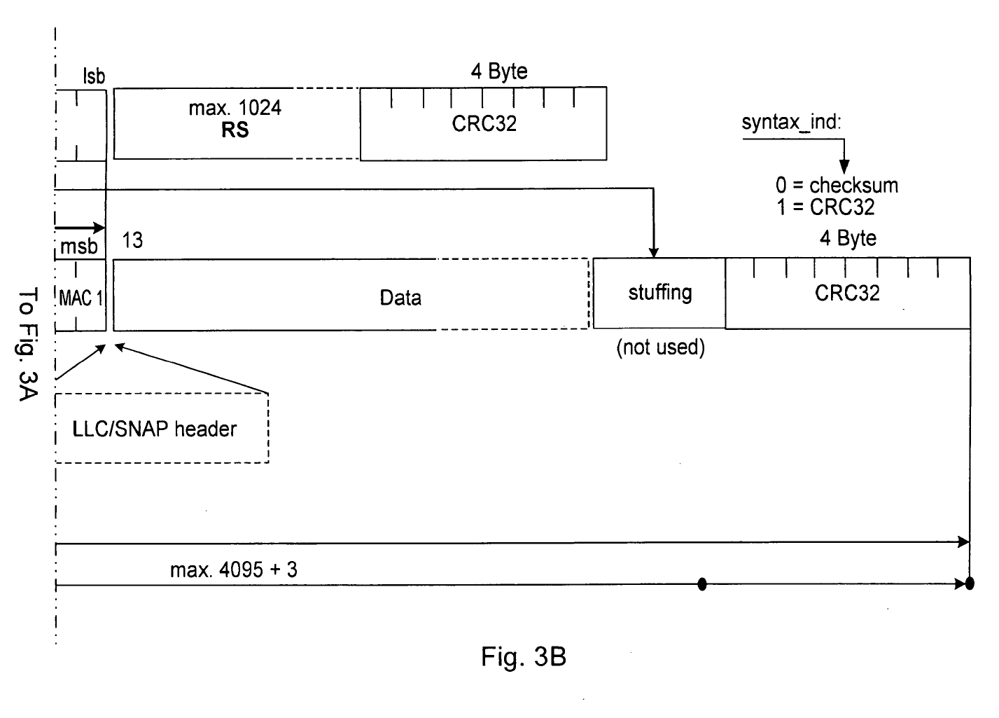

### DETAILED DESCRIPTION OF THE INVENTION

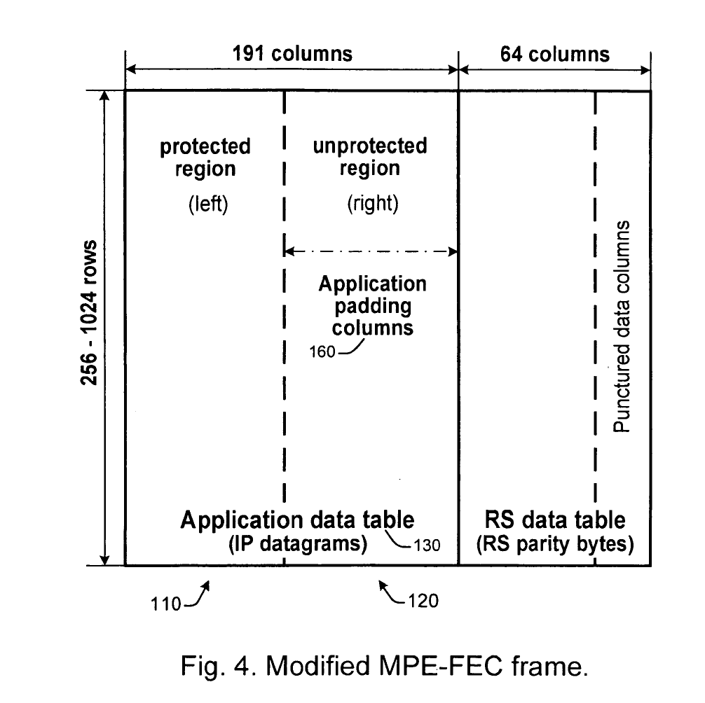

Referring to the drawings wherein like reference numerals refer to like elements, the present invention relates to methods and apparatus for providing UEP via FEC in a time slice through MPE-FEC in DVB-H. While the invention is described herein with respect to DVB-H, it will be appreciated by those skilled in the art that the correction algorithms taught herein may be applied to IP-datagrams used in other modulation formats and transmission schemes such as, for example, VSB, with appropriate modifications made to the algorithms to accommodate the different data syntax of the other schemes. As described herein with respect to the DVB-H format, the invention is based on the modified MPE-FEC frame structure which is shown generally in FIG. 4. Compared to the original MPE-FEC frame, the original ADT derived according to the present invention is preferably virtually partitioned into a “protected region” (PR) 110 and an “unprotected region” (UR) 120 along the column direction of the frame.

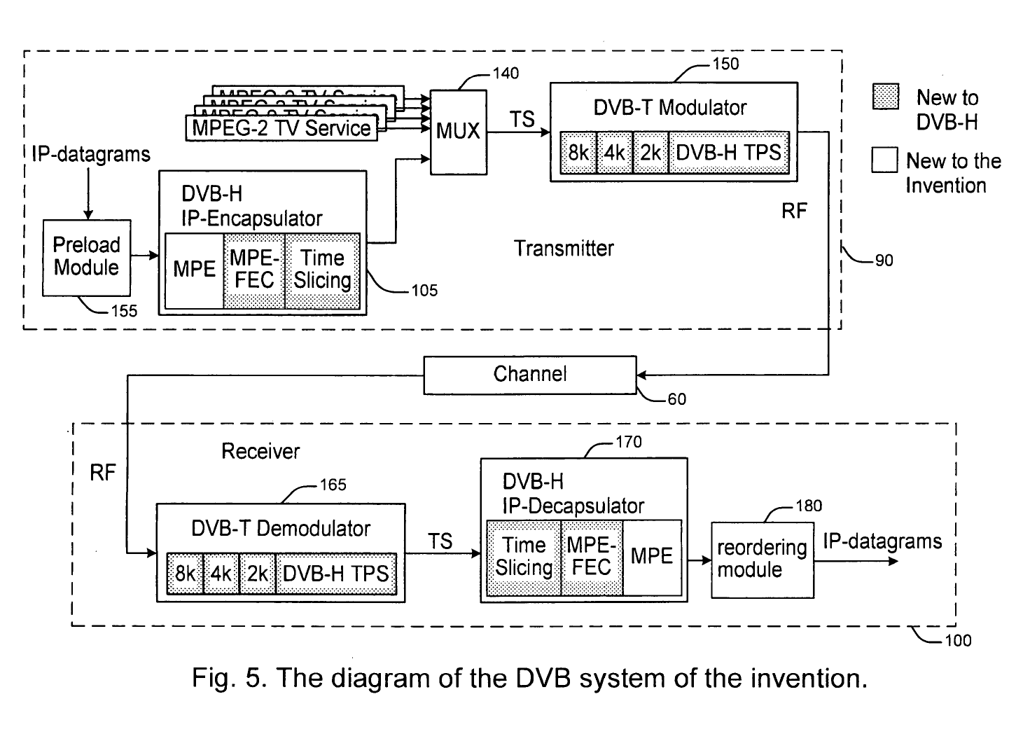

FIG. 5 illustrates a preferred transmission system which accomplishes this result. The system comprises a transmitter end 90 and a receiver end 100. At the transmitter end 90, each IP-datagram is first loaded into the MPE-FEC frame. Unlike the standard operation, in the invention, the IP encapsulator 105 determines the importance of the payload data. If the data is regarded as important, the IP-datagram is introduced into PR 110. Otherwise the data is regarded as unimportant, and the IP-datagram is introduced into UR 120. In each region, IP-datagrams are loaded in the same way as the standard, i.e. column-wise from top to bottom and from left to right.

The partition of ADT 130 can be fixed a priori, or be adjusted dynamically for each MPE-FEC frame according to the characteristics of the data in a time slice. Consider first the fixed partition case. In this case, whenever an IP-datagram is introduced either into PR 110 or UR 120, its start position in the frame is immediately available. Furthermore, the IP encapsulator 105 can determine the last IP-datagram that fills PR 110, which is defined as the last section of the table. With the information available, upon loading an IP-datagram into ADT 130, the IP encapsulator 105 can packetize it into an MPE section, fill the necessary information in the header and forward the section to MUX 140 and the DVB-T modulator 150.

For the dynamic partition case, the position of the boundary between the two regions is unknown until all the IP-datagrams are loaded into the frame. In this case, a pre-loading stage 155 is required. In this stage, the IP encapsulator 105 accumulates the bit rates of both important and unimportant IP-datagrams until the combined bit rate reaches the capacity of ADT 130. With the final bit rates of the two regions, the position of the ADT partition can be determined. The rest of the operations are then the same as the fixed partition case. Note that such operation can also be performed at application layer outside the IP encapsulator 105, such that the IP-datagrams are pre-reordered and forward to the IP encapsulator 105. In this situation, the IP encapsulator 105 is agnostic to the source importance information.

Once PR 110 and UR 120 are properly filled, RS encoding is applied across the columns for each row in the MPE-FEC frame. In the standard, each byte from a row in ADT 130 is treated as a message symbol in RS encoding. In this invention, however, for each row, only the bytes that fall in PR 110 are regarded as message symbols. The byte positions in an RS codeword that fall in UR 120 are regarded as padding, and are filled with zeros during encoding. Suppose the number of columns of UR 120 is x, then an RS (255, 191−x) code is applied for each row of the frame. The RS code rate now is

$$\frac{191 - x}{255} ,$$

which is smaller than the default code rate 0.75 in the standard. With the reduced code rate, the data from PR 110 is provided with stronger FEC protection. Meanwhile, the data from UR 120 receives no FEC protection. Thus a two-level UEP is created for the IP-datagrams in the MPE-FEC frame. Moreover, advantageously the original codeword length of 255 is preserved, so the strength of the code is not compromised.

The strength of the FEC protection for the data in PR 110 can be adjusted flexibly by controlling the size of PR 110 (or equivalently, UR 120). With fewer IP-datagrams in a time slice being treated as important, stronger protection can be obtained for these datagrams, at the cost of more IP-datagrams without FEC protection, and vice-versa. At the two extremes, i.e. all the IP-datagrams are treated as important or unimportant, the UEP in the invention degenerates to the EEP provided by the standard.

When the RS encoding for all the rows in the frame is finished, the parity symbols from each column of RSDT are encapsulated into an MPE-FEC section, and output in the standard's order. To signal the ADT partition information to the receiver, the “padding column” 160 field in each of the MPE-FEC section headers now records the width of UR 120. These MPE-FEC sections are then forwarded to MUX 140 and the DVB-T modulator 150.

Notice that although IP-datagrams are reordered in MPE-FEC frame to fit into PR 110 and UR 120, they can be forwarded to the DVB-T modulator 150 in their original order. Hence any channel burst during transmission is more likely affecting IP-datagrams of both categories of IP-datagrams with equal probability. Hence it effectively mitigates burst errors.

The same loading process as in the standard takes place for the IP decapsulator 170 in the receiver end 100 after the channel 60 inputs the signal to the DVB-T demodulator 165. Every byte position in the MPE-FEC frame that is occupied by an MPE section is marked as “reliable”, regardless of the region the section belongs. If the last MPE section from PR 110 is correctly received, the IP decapsulator 170 can be informed by the end-of-table flag in its header and in turn marks the unoccupied positions in the last column of the section as “reliable”.

After all the correct sections are loaded into the MPE-FEC frame, the IP decapsulator 170 performs erasure-based RS decoding row-wise. Before the decoding, the IP decapsulator 170 retrieves the partition information from the “padding column” 160 field of any received MPE-FEC section header. During the formation of an RS codeword, the RS decoder uses the information and marks those byte positions from UR as “reliable” in each codeword, regardless of its actual status marked in the frame. Normal RS decoding is then performed to recover lost symbols in PR 110, and the IP decapsulator 170 marks the position corresponding to any recovered symbol as “reliable” in the MPE-FEC frame.

After RS decoding, the IP decapsulator 170 outputs those correct IP-datagrams from both PR 110 and UR 120. When the IP decapsulator 170 encounters the last section in PR 110 with flag end-of-table, it outputs the IP-datagram, skips the rest of the last column of the datagram and starts outputting the correct IP-datagrams in UR 120.

In the IP encapsulator 105, IP-datagrams are reordered according to their importance to fit into PR 110 and UR 120 in the MPE-FEC frame. Yet the IP decapsulator 170 outputs IP-datagrams according to the spatial order they are placed in the MPE-FEC frame. So, the order of IP-datagrams output from the IP decapsulator 170 is not the same one as the input IP-datagrams to the IP encapsulator 105. To restore the input order, a reordering module 180 is necessary at the receiver end. The reordering process can be done based on keys such as sequence number or time stamp provided by upper layer protocols. If RTP protocol is used in the application, the packets are reordered based on sequence number as specified in RTP standard.

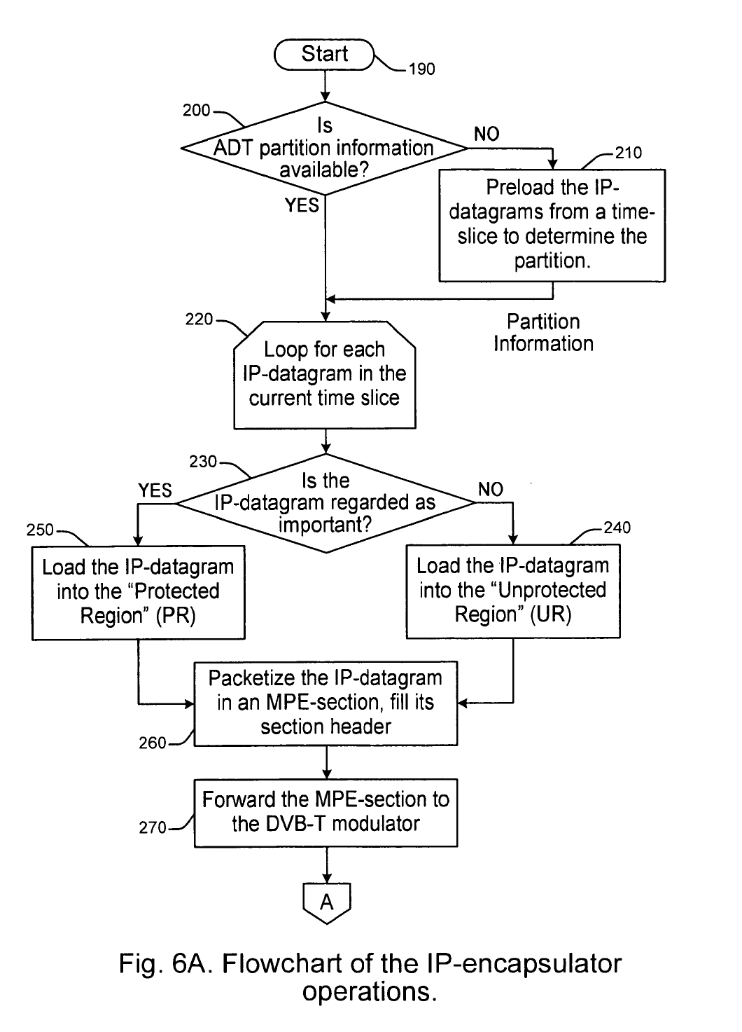

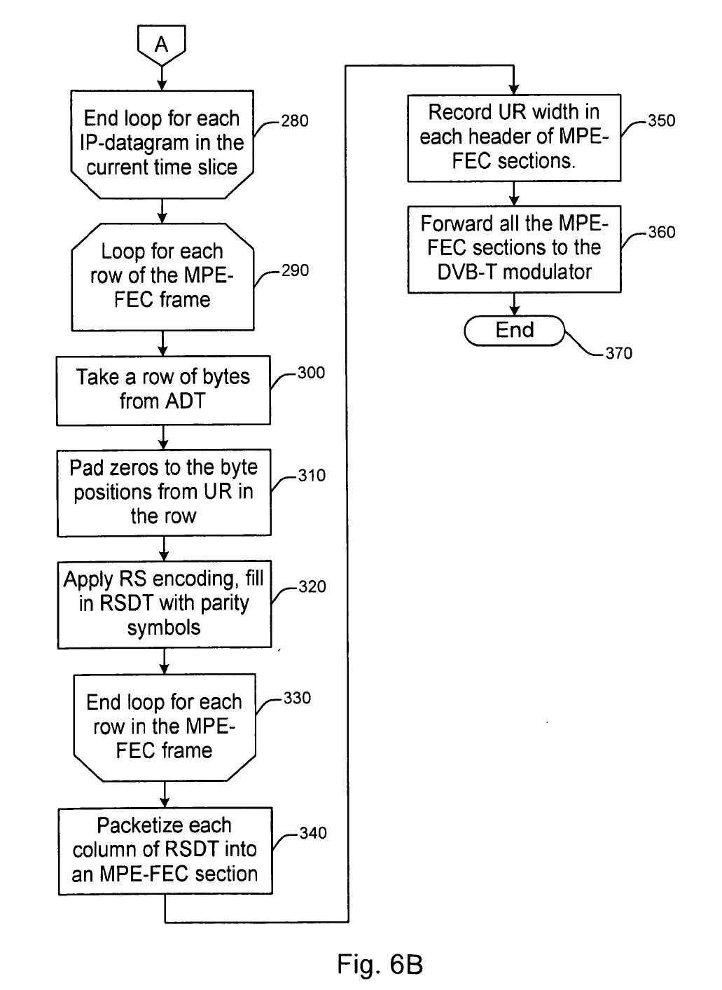

FIG. 6 is an exemplary flow chart of a method of operation of the IP encapsulators of the present invention. It will be appreciated by those skilled in the art that the methods may be implemented in software, hardware or firmware. Further, the methods can be embodied as application specific integrated circuits (ASICs) or in other devices which are adapted to perform the transmission and reception functions described herein.

The methods begin at step 190 and at step 200 it is determined if an ADT partition is available. If not, then at step 210 the IP-datagrams are preloaded from a time slice to determine the partition and the method proceeds to step 220. If so, then the method proceeds directly to step 220 wherein a loop for each IP-datagram in the time slice is performed. It is then preferably determined at step 230 whether the IP-datagram is regarded as important. If not, then the method proceeds to step 240 wherein the IP-datagram is loaded into the UR. If so, then the method proceeds to step 250 wherein the IP-datagram is loaded into the PR. In either case, at step 260 the IP-datagram is packetized in an MPE-section and its section header is filled.

The method then proceeds to step 270 wherein the MPE-section is forwarded to the DVB-T modulator. At step 280, and end loop is performed for each IP-datagram in the current time slice and the method proceeds to step 290 wherein a loop is performed for each row of the MPE-FEC frame. At step 300 a row of bytes is then taken from the ADT and at step 310 zeros are padded in the byte positions from the UR in the row. Then, it is preferable at step 320 to apply RS encoding and to fill in the RSDT with parity symbols.

It is then desired to perform a loop for each row in the MPE-FEC frame at step 330, and at step 340 to packetize each column of RSDT into an MPE-FEC section. At step 350, the UR width is then recorded in each header of the MPE-FEC sections, and all of the MPE-FEC sections are forwarded to the DVB-T modulator at step 360. The method then ends at step 370.

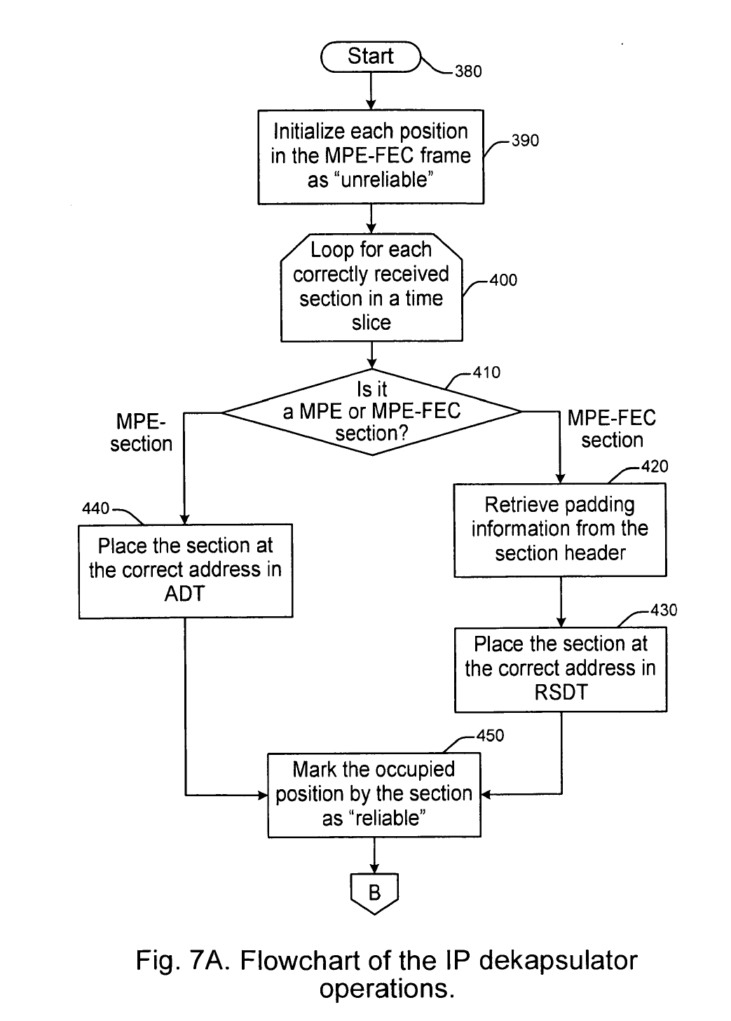

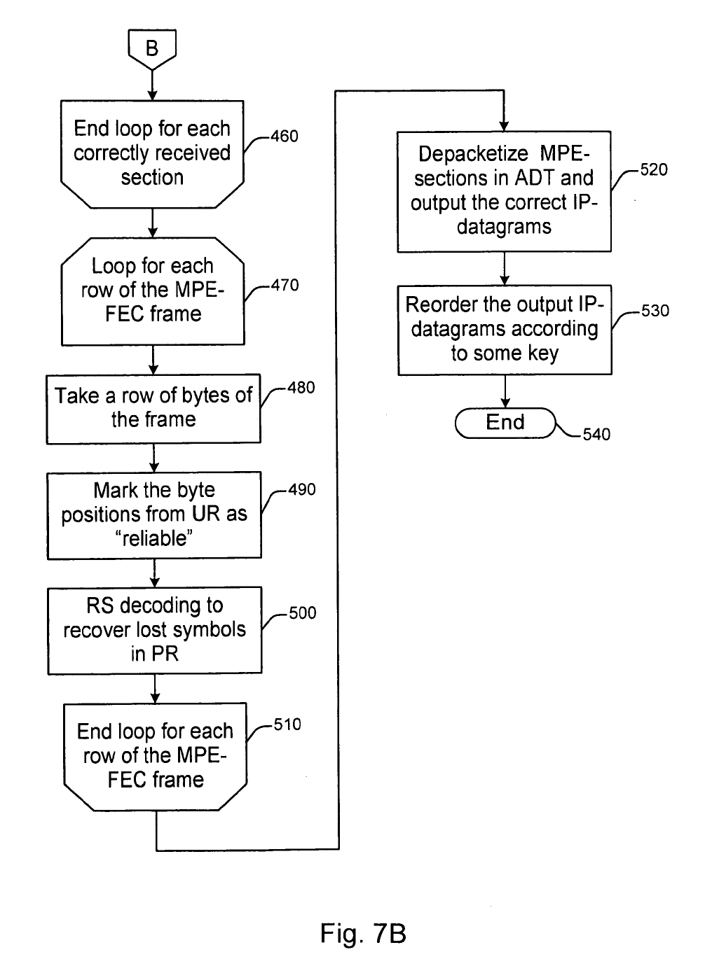

FIG. 7 is a flow chart of a preferred method for IP decapsulator operation of the present invention. The method starts at step 380, and at step 390 each position in the MPE-FEC frame is initialized as unreliable. It is then preferred at step 400 to perform a loop for each correctly received section in a time slice. More preferably, it is then determined at step 410 whether an MPE or MPE-FEC section is received. If not, then at step 420 padding information is retrieved from the section header and at 430 the section is placed at the correct address in RSDT. If so, then at step 440 the section is placed at the correct address in the ADT. In either case, the method then proceeds to step 450 wherein the position is marked occupied by the section as reliable.

It is then further desirable to perform an end loop at step 460 for each correctly received section, and at step 470 to perform a loop for each row of the MPE-FEC frame. At step 480, a row of bytes is taken for the frames and at step 490 the byte positions are marked from the UR as reliable. RS decoding is then preferably performed at step 500, and at step 510 a loop is performed for each row of the MPE-FEC frame. At step 520 the MPE-sections are depacketized in the ADT and the correct IP-datagrams are output. The method then reorders at step 530 the output IP-datagrams according to a desired key, and the method stops at step 540.

There have thus been described certain preferred embodiments of methods and apparatus for performing different data loss protections in accordance with the present invention. While preferred embodiments have been described and disclosed, it will be appreciated by those with skill in the art that modifications are within the true spirit and scope of the invention. The appended claims are intended to cover all such modifications.

1. A method, comprising the steps of
partitioning a data word into a protected region and an unprotected region to provide unequal error protection of frames through the link layer forward error correction (FEC) in a DVB-H system.

2. The method recited in claim 1, wherein the partitioning comprises pre-loading the frame from a time slice to determine a partition.

3. The method recited in claim 2, further comprising the step of determining whether the data in the frame is important.

4. The method recited in claim 3, further comprising the step of loading the data into the protected region if the data is determined to be important, and loading the data into the unprotected region otherwise.

5. The method recited in claim 4, further comprising the step of packetizing the data in a packet (MPE section) and fill the packet (MPE section) header.

6. The method recited in claim 5, further comprising the step of modulating the data for transmission.

7. The method recited in claim 1, further comprising the step of treating the byte positions from the unprotected region as zeros when forming the message bits of an FEC codeword during FEC coding.

8. The method recited in claim 1, further comprising the step of reusing the “padding column” field in the MPE-FEC section header to record the width of the unprotected region in the MPE-FEC matrix.

9. An encoder comprising:
a first stage for loading data frames to an encoding stage for determining a protected region and an unprotected region;
a modulator interfaced to the first stage for encoding the data; and
a forward error correction encoding stage for providing unequal forward error correction to the frames in accordance with the importance of the data determined by the protected and unprotected regions of the frames, through the link layer forward error correction of a DVB-H system.

10. The encoder recited in claim 9, wherein the first stage comprises a pre-loading stage for partitioning the frame from a time slice to determine a partition.

11. The encoder recited in claim 10, further comprising means in communication with the pre-loading stage for determining whether the data in the frame is important.

12. The encoder recited in claim 11, further comprising means in communication with the pre-loading stage for loading the data into the protected region if the data is determined to be important, and loading the data into the unprotected region otherwise.

13. The encoder recited in claim 9, further comprising means for padding zeros in byte positions from the unprotected region when forming the message bits of an FEC codeword during FEC encoding.

14. A decoder comprising:
a decapsulator for receiving from a channel an encoded data frame which has been coded to into a protected region and an unprotected region through the link layer forward error correction of a DVB-H system; and
a forward error correction decoding stage to retrieve the partition information of the protected region and the unprotected region, and further apply decoding only to the data from the protected region;
a stage adapted to receive the output of the decapsulator for examining the protected region and the unprotected region to determine the importance of the frame.

15. The decoder recited in claim 14, wherein the stage comprises a reordering stage for reordering and outputting data in the frame based on certain ordering key to have the same output order as the input data.

16. The decoder recited in claim 14, wherein the decapsulator comprises means for retrieving padding information from the FEC packet header (MPE-FEC section header).

17. The decoder recited in claim 16, wherein the decapsulator comprises decoding means for decoding the frames after it has been determined that the frame is reliable.

18. The decoder recited in claim 17, further comprising means for retrieving padding zeros from the frame FEC packet header (MPE-FEC section header).
